(19) United States
(12) Patent Application Publication
(10) Pub. No.: US 2025/0044357 A1
(43) Pub. Date: Feb. 6, 2025

(54) TECHNIQUES FOR MEASURING BATTERY SYSTEM STATE OF POWER

(71) Applicant: FCA US LLC, Auburn Hills, MI (US)

(72) Inventors: Junran Chen, Hamilton (CA); Phillip Kollmeyer, Buffalo, NY (US); Satyam Panchal, Breslau (CA); Yasaman Masoudi, Windsor (CA)

(21) Appl. No.: 18/362,385

(22) Filed: Jul. 31, 2023

(51) Int. Cl. G01R 31/367; G01R 31/36; H01M 10/44

(52) U.S. Cl. CPC G01R 31/367; G01R 31/3648; H01M 10/446; H01M 2220/20

(57) ABSTRACT

A state of power (SOP) measurement technique includes determining an initial power command corresponding to a potential SOP of a battery system and performing an iterative power command searching process including charging the battery system to a fully-charged state of charge (SOC), discharging the battery system to a set of SOC breakpoints until the battery system reaches a fully-discharged SOC, after reaching each SOC breakpoint, applying a power command as a constant power pulse to the battery system, the power command being the initial power command or a subsequently updated power command, and based on whether a current or voltage of the battery system exceeds an error tolerance, updating the initial power command and repeating the iterative power command searching process, or outputting the initial power command or the subsequently updated power command as a measured SOP of the battery system.

### FIELD

The present application generally relates to battery systems and, more particularly, to techniques for measuring battery system state of power.

### BACKGROUND

An electrified vehicle has an electrified powertrain including one or more battery systems that provide electrical energy (i.e., current) to power one or more electric motors and receive electrical energy from various possible sources for recharging. The power that a battery system can provide/receive is a finite value limited by the battery cell structure and its chemical reactions therein. To ensure the battery system remains within a safe operating region, the maximum power that the battery system can supply to loads (e.g., an electric motor) or receive (e.g., via an external charging station or a regenerative braking system) before reaching a respective voltage, current, state of charge (SOC), and/or temperature limit must be accurately determined to avoid malfunctions or faults. These power limits are also known as the battery system's power capability or state of power (SOP). Battery system SOP cannot be directly measured with a sensor and instead requires a unique measurement or estimation procedure based on other parameters.

Battery system SOP can be measured or estimated via offline techniques in which tests are performed on the battery system in a laboratory environment, or through online estimation techniques in which an algorithm estimates SOP during regular operation (i.e., driving for an electrified vehicle). While there are a number of common offline and online SOP estimation techniques, in which SOP is calculated from measured values or a model, the accuracy of estimation techniques can only be verified with a true measurement of SOP. An SOP measurement technique, by contrast, measures SOP through an iterative method, and in the final iteration applies the actual measured SOP pulse to the battery, thereby demonstrating that at the final timestep of the pulse the voltage, current, SOC, and/or temperature limit is reached. While such SOP measurement techniques are necessary to validate both online and offline SOP estimation methods, there are currently no widely accepted methods to measure SOP accurately (in contrast to other battery parameters, such as SOC and state of health, or SOH). Accordingly, there exists an opportunity for improvement in the relevant art.

### SUMMARY

According to one example aspect of the invention, a state of power (SOP) measurement system for a battery system is presented. In one exemplary implementation, the SOP measurement system comprises a set of sensors configured to measure a set of parameters of the battery system, the set of parameters including at least a state of charge (SOC) and a current or voltage of the battery system and a control system configured to determine an initial power command corresponding to a potential SOP of the battery system and perform an iterative power command searching process including preparing the battery system by charging the battery system to a fully-charged SOC, discharging the battery system to a set of SOC breakpoints until the battery system reaches a fully-discharged SOC, after reaching each SOC breakpoint, applying a power command as a constant power pulse to the battery system, the power command being the initial power command or a subsequently updated power command, when a current or voltage of the battery system exceeds an error tolerance, updating the initial power command and repeating the iterative power command searching process, and when the current or voltage of the battery system does not exceed the error tolerance, outputting the initial power command or the subsequently updated power command as a measured SOP of the battery system.

In some implementations, the initial power command is a power based on an SOP estimation algorithm to be validated, and wherein the SOP estimation algorithm to be validated is one of a battery model-based SOP estimation algorithm and a machine learning-based SOP estimation algorithm. In some implementations, the initial power command is a power determined using a pulse-based battery test. In some implementations, the pulse-based battery test is one of a hybrid power pulse characterization (HPPC) test, a constant voltage (CV) test, a constant current (CC) test, and a constant current, constant voltage (CCCV) or constant power (CP) test. In some implementations, the fully-charged SOC is approximately 100% and the fully-discharged SOC is approximately 0%.

In some implementations, the set of parameters of the battery system further includes an internal temperature of the battery system, the battery system is placed in a thermal chamber that is temperature-controlled by the control system, and the preparing of the battery system further includes the internal temperature of the battery system achieving a desired temperature. In some implementations, the iterative power capability searching technique further comprises determining an open circuit voltage (OCV) of the battery system after the discharging and a rest period. In some implementations, the discharging of the battery system is a constant discharge rate. In some implementations, the discharging of the battery system is a vehicle drive cycle discharge or a load profile for an application of interest. In some implementations, the battery system is a high voltage battery system of an electrified powertrain of an electrified vehicle, and wherein the control system is configured to output the measured SOP of the high voltage battery system into a controller of the electrified vehicle that utilizes the measured SOP of the high voltage battery system for control of the electrified powertrain.

According to another example aspect of the invention, an SOP measurement method for a battery system is presented. In one exemplary implementation, the SOP measurement method comprises providing a set of sensors configured to measure a set of parameters of the battery system, the set of parameters including at least a state of charge (SOC) and a current or voltage of the battery system and providing a control system configured to determine an initial power command corresponding to a potential SOP of the battery system and perform an iterative power command searching process including preparing the battery system by charging the battery system to a fully-charged SOC, discharging the battery system to a set of SOC breakpoints until the battery system reaches a fully-discharged SOC, after reaching each SOC breakpoint, applying a power command as a constant power pulse to the battery system, the power command being the initial power command or a subsequently updated power command, when a current or voltage of the battery system exceeds an error tolerance, updating the initial power command and repeating the iterative power command searching process, and when the current or voltage of the battery system does not exceed the error tolerance, outputting the initial power command or the subsequently updated power command as a measured SOP of the battery system.

In some implementations, the initial power command is a power based on an SOP estimation algorithm to be validated, and wherein the SOP estimation algorithm to be validated is one of a battery model-based SOP estimation algorithm and a machine learning-based SOP estimation algorithm. In some implementations, the initial power command is a power using a pulse-based battery test. In some implementations, the pulse-based battery test is one of an HPPC test, a CV test, a CC test, and a CCCV or constant power CP test. In some implementations, the fully-charged SOC is approximately 100% and the fully-discharged SOC is approximately 0%.

In some implementations, the set of parameters of the battery system further includes an internal temperature of the battery system, the battery system is placed in a thermal chamber that is temperature-controlled by the control system, and the preparing of the battery system further includes the internal temperature of the battery system achieving a desired temperature. In some implementations, the iterative power capability searching technique further comprises determining an OCV of the battery system after the discharging and a rest period. In some implementations, the discharging of the battery system is a constant discharge rate. In some implementations, the discharging of the battery system is a vehicle drive cycle discharge or a load profile for an application of interest. In some implementations, the battery system is a high voltage battery system of an electrified powertrain of an electrified vehicle, and wherein the control system is configured to output the measured SOP of the high voltage battery system into a controller of the electrified vehicle that utilizes the measured SOP of the high voltage battery system for control of the electrified powertrain.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIGS. 1A and 1B are a functional block diagram of an example state of power (SOP) measurement system for a battery system and an example open circuit voltage-resistance (OCV-R) equivalent circuit model according to the principles of the present application;

FIG. 1C is a functional block diagram of an electrified vehicle having an example battery management system according to the principles of the present application;

FIG. 2A is a flow diagram of an example SOP measurement method for a battery system according to the principles of the present application;

FIG. 2B is a diagram illustrating an iterative power command searching process to measure the SOP of a battery system according to the principles of the present application; and

FIGS. 3A-3E are example plots illustrating comparative performance of a conventional SOP estimation technique and the SOP measurement technique according to the principles of the present application.

### DESCRIPTION

As previously discussed, conventional state of power (SOP) estimation algorithms are lacking and there are no widely accepted methods to measure/estimate SOP accurately, in contrast to other battery system parameters such as state of charge (SOC) and state of health (SOH). The most common conventional offline SOP estimation technique is a hybrid pulse power characterization (HPPC) test method, which determines battery discharging and charging internal resistance from the application of current pulses at different SOCs and then uses an open circuit voltage-resistance (OCV-R) battery equivalent circuit model (ECM) to calculate SOP. The battery's internal resistance varies when applied with different magnitudes of current pulses, especially at low temperatures. Moreover, during the HPPC test method, the current magnitude of the battery is usually different from when the battery reaches the current or voltage limit. Therefore, the battery's internal resistance calculated from it is not accurate, especially at low temperatures. Thus, the HPPC test method is not guaranteed to provide accurate battery power capability values. Other conventional offline estimation techniques include constant voltage (CV), constant current (CC), and constant current, constant voltage (CCCV) test methods.

In the CV and CC offline SOP estimation methods, the battery voltage or current is set for a given pulse time to the lowermost threshold for discharging or uppermost threshold for charging and the battery current or voltage is recorded against time. The pulse will terminate early if the current limit is reached during a CV pulse or if the voltage limit is reached during a CC pulse. The SOP based on the voltage limitation or current limitation is then obtained by multiplying the recorded battery current and voltage at the last time step of the pulse. The CCCV test method is similar except that the pulses do not terminate early if the voltage or current limits are reached, they instead continue while operating at the current or voltage limit thresholds. For example, for a CCCV discharge pulse, constant current will be applied and if the lower voltage limit is reached, current will be reduced to regulate the voltage at that value. In this way, the commanded pulse length (e.g., 10 seconds) will always be achieved during a CCCV test, but the pulse may be constant current for part of the pulse time and constant voltage for part of the pulse time. Similar to the CV or CC test methods, the SOP is then calculated by multiplying the voltage and current at the end of the pulse. These test methods achieve a more accurate offline estimation of SOP compared to the HPPC test because the battery continuously operates at maximum current or maximum voltage during the tests, ensuring the test conditions are more similar to an actual constant power pulse at the maximum power capability. However, the power value applied to the cell varies when operating at CC, CV, or CCCV mode. According to the definition of SOP, the accuracy of SOP can only be genuinely verified by an actual constant power pulse test. Therefore, these tests also cannot guarantee the accuracy of their measured power capability values.

One offline SOP measurement technique is a constant power test method. In the constant power test method, a CCCV test method is first performed to get a first iteration SOP estimate that is then applied as a constant power pulse to the battery. Based on the voltage error, this method then modifies the next iteration SOP with a specific power increment (e.g., 2 Watts, or W) and then applies it to the battery iteratively. This iterative process will be terminated when the voltage error is within the tolerance. Since this method applies a constant power pulse to the battery, its accuracy can be intuitively evaluated by the gap between the pulse end-time voltage and the voltage limit. Because power is varied at a set increment each iteration, it will need a considerable number of iterations if higher SOP precision, for example, 0.1 W, is required, possible prematurely aging the battery and impacting the SOP result. Each iteration also takes considerable time since the battery needs to be charged/discharged back to the pre-pulse SOC level and needs time to cool between pulses. In addition, this test method only considers voltage-limited SOP and ignores the current-limited, temperature, and SOC-limited cases. Finally, batteries have long electrochemical dynamics, which will be impacted by the application of consecutive power pulses, resulting in the power measured by this technique being inaccurate, especially for certain battery chemistries (e.g., lithium iron phosphate, or LiFePO₄) and low temperatures.

Accordingly, the present application is directed to improved offline SOP measurement systems and methods for a battery system, such as battery systems for electrified vehicles. While electrified vehicles are specifically discussed herein, it will be appreciated that the battery system SOP measurement systems/methods of the present application are applicable to any suitable battery systems, including non-vehicle applications (e.g., consumer electronics, electrified aircraft, and electrified marine vessels). These battery systems and methods utilize a new, unique test method for accurately measuring the SOP of an electrified vehicle's battery system or validating the accuracy of offline or online SOP estimation algorithms or measurement methods. This test method can also be described as an iterative power capability searching method. In the beginning, an initial power command is selected and applied at different SOC breakpoints. This initial power command could be any suitable value, as the iterative searching process will eventually narrow in on the actual, measured SOP of the battery system. Two specific examples of the initial power command are (i) a power determined using a conventional pulse-based offline SOP estimation (HPPC, CV, CC, CCCV, etc.) and (ii) a power based on another offline or online SOP estimation algorithm.

After fully charging (e.g., and achieving a desired temperature, such as in a temperature-controlled chamber environment), the battery system is discharged (e.g., constant current discharge, or vehicle drive cycle discharge, such as for the UDDS or USO6 drive cycle, etc.) to specific SOC breakpoints, and corresponding power commands (P_{SOC_BREAKPOINT}) will be applied as constant power pulses of time length T to the battery system, with the discharge and power pulse steps being repeated until the battery system reaches the final SOC breakpoint SOC_{END} and is therefore fully depleted. When any one of the voltage or current values at the end of the constant power pulses are not within an error tolerance, the power command values for the corresponding SOC breakpoints will be updated. The battery system will be fully charged and the process will be repeated until a power command iteration results in no error tolerance being exceeded. Fully recharging the battery and repeating the discharge and power pulse process ensures that each power pulse has the same history, i.e., the same discharge profile in the recent past, which is a critical feature of the present application because it ensures that the method works for batteries with strong history-dependent properties like LiFePO₄ chemistries. The primary benefit is a highly accurate battery system SOP measurement, which potentially results in extended battery system usage (and increased vehicle/fuel efficiency), increased battery system life, and thermal runaway and/or other damage (e.g., overloading) prevention (which could reduce replacement/warranty costs).

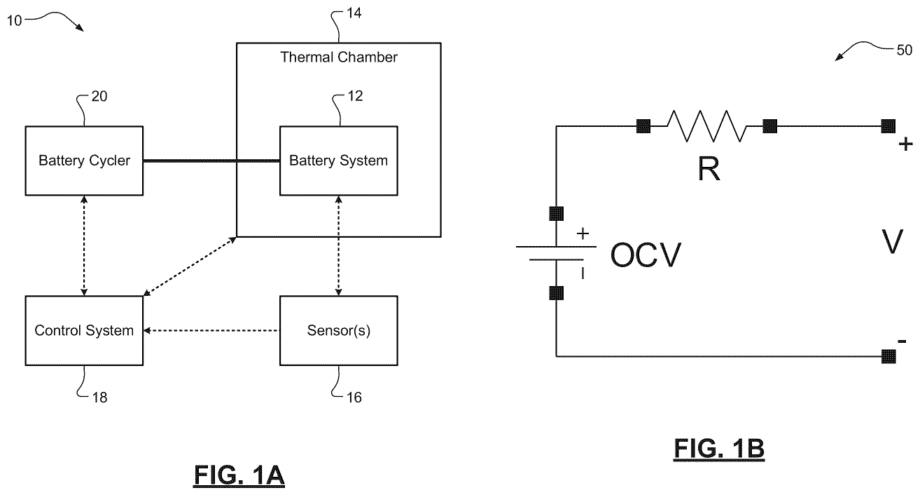

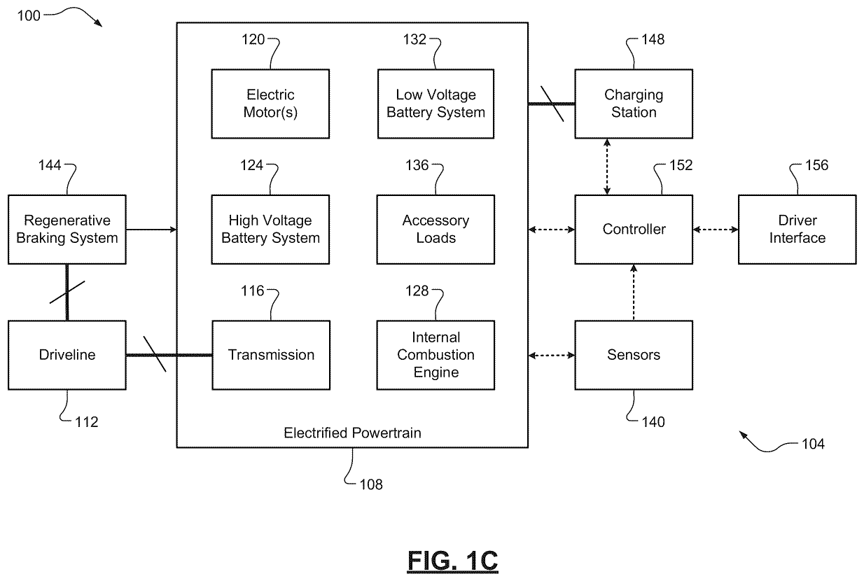

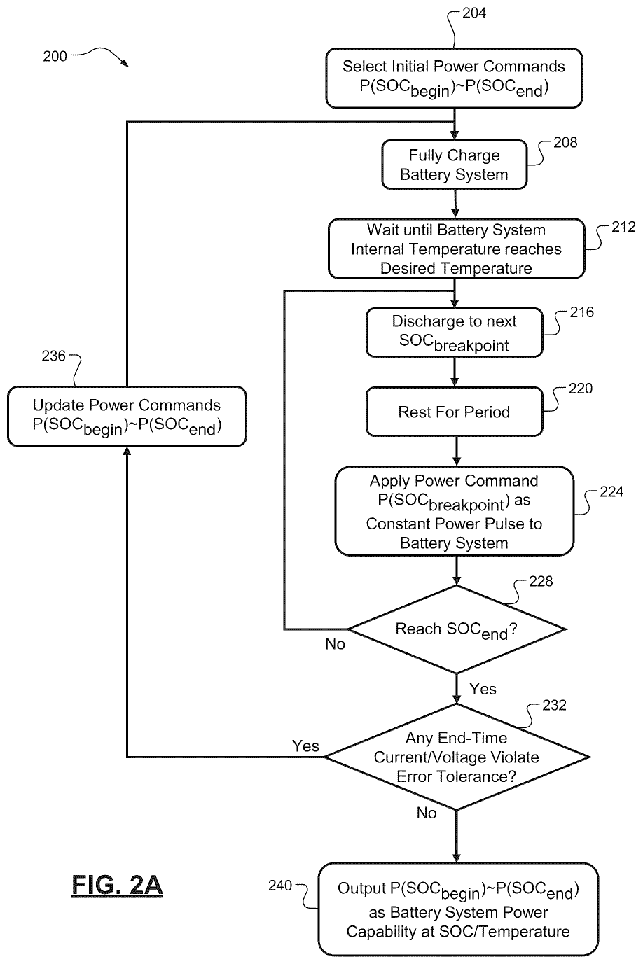

Referring now to FIGS. 1A and 1B, a functional block diagram of an example SOP measurement system 10 for a battery system 12 and an example open-circuit voltage-resistance (OCV-R) equivalent circuit model 50 for the battery system 12 according to the principles of the present application is illustrated. The SOP measurement system 10 could be utilized in an offline (e.g., a lab) testing environment (i.e., not online by a vehicle controller). The battery system 12 is placed in a temperature-controlled or regulated thermal chamber 14 such that the temperature of the battery system 12 can be controlled so its internal temperature reaches a desired temperature for SOP measurement. A set of one or more sensors 16 are configured to measure electrical and thermal parameters of the battery system 12, such as voltage, current, and temperature. A control system or controller 18 (e.g., a computer system) is configured to execute software to perform the SOP measurement process according to the present application. This includes, for example, controlling the thermal chamber 14 to a desired temperature and controlling charging/discharging of the battery system 12 via a battery cycler 20, while also measuring parameters of the battery system 12 using the sensor(s) 16. This process will be described in greater detail below.

Referring now to FIG. 1C, a functional block diagram of an electrified vehicle 100 having an example battery management system (also referred to as “BMS”) 104 according to the principles of the present application is illustrated. The electrified vehicle 100 is propulsively powered by an electrified powertrain 108 that generates and transfers drive torque to a driveline 112 via a transmission 116 (e.g., a single-speed or multi-speed automatic transmission). The electrified powertrain 108 includes one or more electric motors 120 powered by a high voltage battery system 124 and an optional internal combustion engine 128 configured to combust a mixture of air and fuel (diesel, gasoline, etc.). In other words, as the one or more electric motors 120 are operated to generate drive torque (torque consumer mode), the SOC of the high voltage battery system 124 is depleted. The high voltage battery system 124 could be, for example, a lithium-ion based battery pack. The electrified powertrain 108 also includes a low voltage battery system 132 (e.g., a 12 volt lead-acid or lithium-ion battery system) configured to power low voltage loads of accessory loads 136 of the electrified vehicle 100 (lights, gauges, displays, etc.). Some of the accessory loads 136 may be high voltage accessory loads powered by the high voltage battery system 124, such as pumps, fans, compressors, heaters, and the like.

A direct current (DC) to DC converter (not shown) or other suitable system could be implemented between the high and low voltage battery systems 124, 132 for stepping up/down respective DC voltages (e.g., for recharging therebetween). The electrified powertrain 108 also includes a regenerative braking system 140 is configured to brake (decelerate) the driveline 116 and convert the kinetic energy to electrical energy, such as for recharging the high voltage battery system 124. In certain configurations (e.g., plug-in hybrid electric vehicle, or PHEV, configurations), the high voltage battery system 124 could also be recharged using an external charging station 144 (e.g., a roadside or residential charging station) and electrified vehicle supply equipment (EVSE). A set of sensors 148 measure operational parameters of the electrified powertrain 108, such as speeds, altitude, current/voltage/temperature, SOC, and the like. A controller 152 controls operation of the electrified vehicle 100, including controlling the electrified powertrain 108 to satisfy a torque request (e.g., via a driver interface 156, such as an accelerator pedal). It will be appreciated that the torque request may not come directly from the driver, but instead could be a torque request generated by an advanced driver assistance (ADAS) or autonomous driving system. The controller 152 is also configured to perform at least a portion of battery management techniques of the present application, which will now be described in greater detail with reference to a method flowchart.

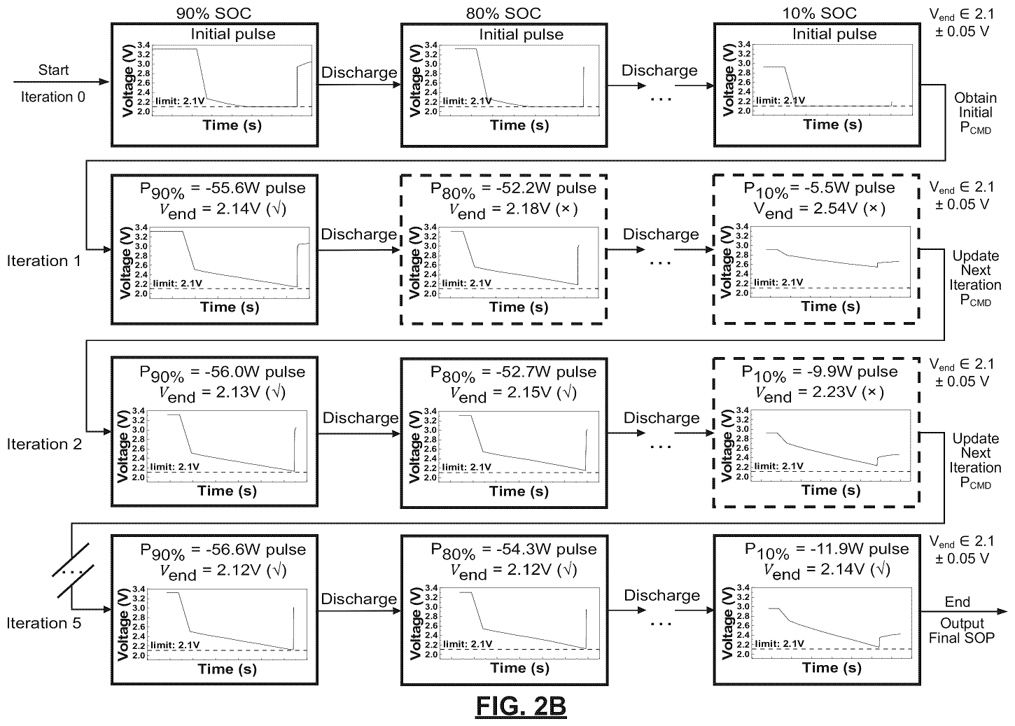

Referring now to FIG. 2A and with continued reference to FIGS. 1A-1C, a flow diagram of an example SOP measurement method 200 for the battery system 12 according to the principles of the present application is illustrated. This method 200 is applicable to any battery system 12, including offline SOP measurement of the high voltage battery system 124 of the electrified vehicle 100, which could be determined by the control system 16 and then loaded into the controller 152 of the electrified vehicle 100 for various uses. At 204, the control system 16 begins the iterative power capability searching technique to estimate the SOP of the battery system 12. First, the control system 12 selects initial power commands. This could be, for example, any suitable power command, such as (i) a power (based on current/voltage) determined using a conventional pulse-based test (HPPC, CV, CC, CCCV, etc.) and (ii) a power based on another offline or online SOP estimation algorithm. At 208, the control system 16 fully charges the battery system 12 to a first SOC (e.g., at a one-hour charge rate, or C rate) corresponding to a fully-charged battery system. This first SOC could be, for example, 100%, but it will be appreciated that it could also be slightly less than 100%, such as 98%. At 212, the control system 16 waits until an internal temperature of the battery system 12 achieves a desired temperature. This could include thermal conditioning (heating/cooling the thermal chamber 14) and then monitoring the battery system internal temperature. The desired temperature could be, for example any of a number of temperatures (−20° C., −10° C., 0° C., 10° C., 20° C., 25° C., 40° C., etc.).

Next, at 216, the control system 16 discharges the battery system 12 to a first SOC breakpoint (SOC_{breakpoint}) at a first discharge rate. This first SOC breakpoint SOC_{breakpoint} could be, for example, approximately 5% less than the first SOC, or ˜95%. The term “SOC breakpoint” as used herein refers to each SOC level that is desired to be tested. SOC breakpoints may be selected based on where the behavior of the battery cells of the battery system 124 begins to change (e.g., its charging/discharging characteristics), such as due to its chemistry. To discharge to the next SOC breakpoint, any type of discharge profile may be used, for example, a constant current discharge rate or a drive cycle profile discharging (UDDS, USO6, etc.). Powe capability is dependent on how the battery system 12 is discharged, so the discharge profile should be chosen accordingly. Once the first SOC breakpoint SOC_{breakpoint} is reached, the method 200 continues to 220 where the control system 16 waits for a rest period (e.g., ˜5 seconds) such that the battery system 12 has a chance to stabilize and have its OCV, or pseudo/approximate OCV, determined. At 224, the control system 16 applies an initial power command P(SOC_{breakpoint}) as a constant power pulse to the battery system 12. At 228, the control system 16 determines whether the SOC of the battery system 12 has reached its end value SOC_{end}. When false, the method 200 continues and returns to 216. When true, the method 200 proceeds to 232. At 232, the control system 16 determines whether any end-time currents/voltages violated an error tolerance (e.g., +/−0.05 volts). When false, the method 200 proceeds to 240 where the current iteration's power command is output as the final SOC measurement for the battery system 12 and the method 200 ends. When false, however, the method 200 continues to 236 where the control system 16 updates the power command for a next iteration and the method 200 returns to 208 and the iterative process repeats.

As part of the above, the OCV-R battery model 50 (FIG. 1B) can be used to update the battery power command for each iteration. As discussed above, the OCV is determined after the rest periods during the method 200. The measured current and voltage at the end of the power pulse (I_{end} and V_{end}) are used to calculate the battery internal resistance as:

$$R = \vert \frac{{V}_{e n d} - OCV}{{I}_{e n d}} \vert .$$

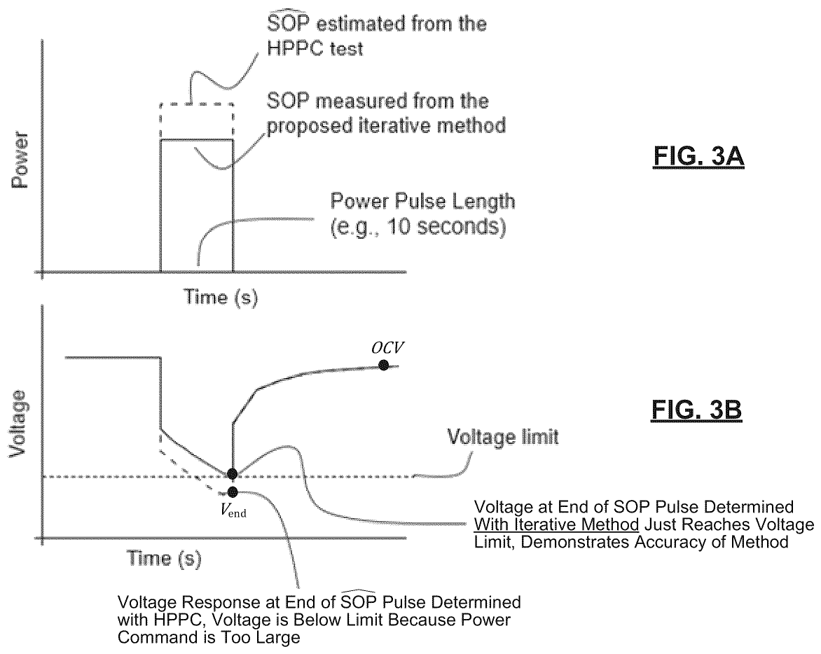

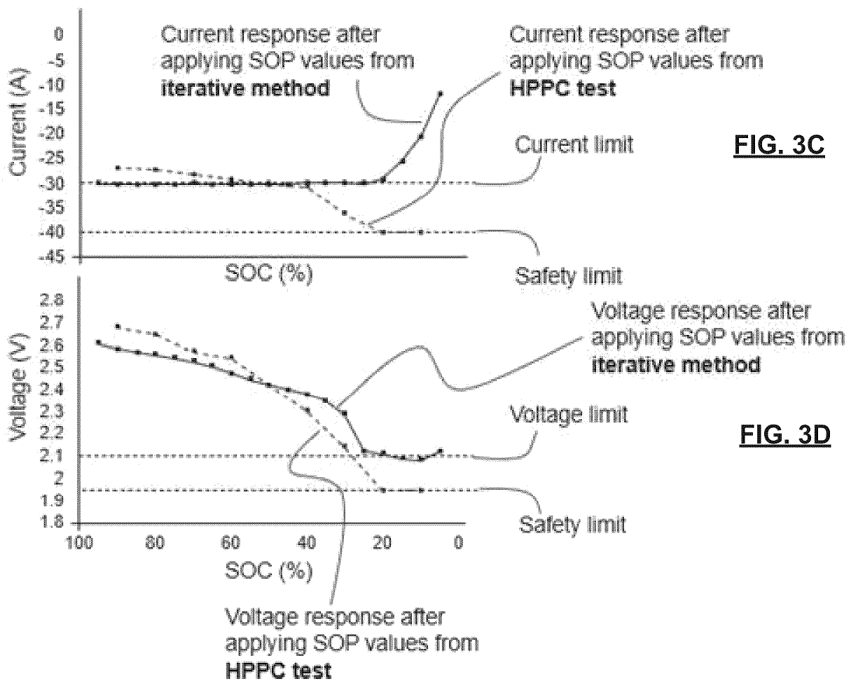

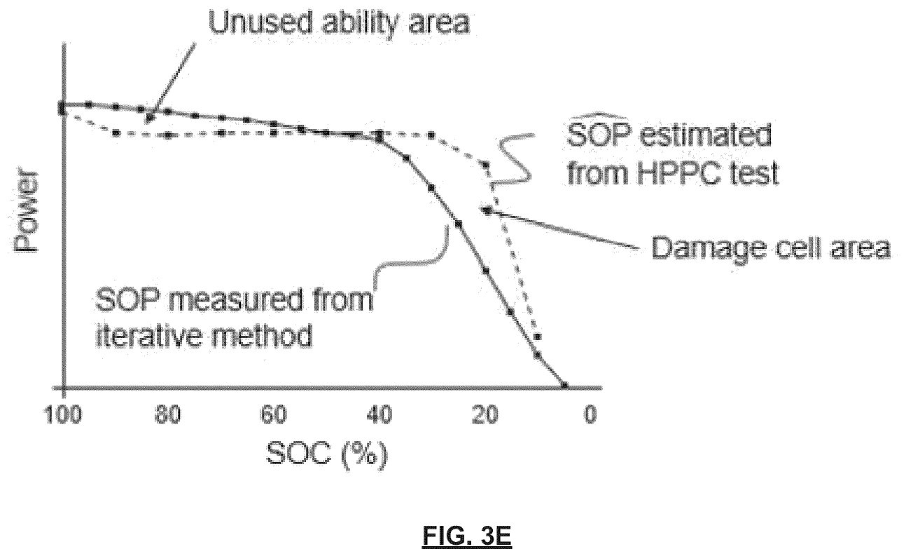

The voltage at the end of the power pulse V_{end} and the OCV are also illustrated in the voltage versus time plot of FIG. 3B. After calculating R using the OCV-R battery model, the next-iteration power capability Pₖ₊₁ can be calculated as follows:

$$Current - limited discharging power capability : \{ \begin{matrix}{V}_{est} = O CV - {I}_{dis - max} \times R \\ {P}_{I - dis} = {I}_{dis - max} \times {V}_{est} , {V}_{est} > {V}_{min}\end{matrix}$$

$$Voltage - limited discharging power capability : \{ \begin{matrix}{I}_{est} = ( O C V - {V}_{min} ) / R \\ {P}_{V - d i s} = {V}_{min} \times {I}_{est} , {I}_{est} < {I}_{max}\end{matrix}$$

$$Current - limited discharging power capability : \{ \begin{matrix}{V}_{est} = OCV + {I}_{char - max} \times R \\ {P}_{I - char} = {I}_{char - max} \times {V}_{est} , {V}_{est} < {V}_{max}\end{matrix}$$

$$Voltage - limited charging power capability : \{ \begin{matrix}{I}_{est} = ( {V}_{max} - O CV ) / R \\ {P}_{V - char} = {V}_{max} \times {I}_{est} , {I}_{est} < {I}_{max}\end{matrix}$$

$$Discharging power capability : {P}_{d i s} = MIN ( \vert {P}_{I - dis} \vert , \vert {P}_{V - d i s} \vert )$$

$$Charging power capability : {P}_{char} = MIN ( \vert {P}_{I - char} \vert , \vert {P}_{V - char} \vert )$$

In the above, OCV is the open circuit voltage, I_{end} and V_{end} are the measured current and voltage at the end of the power pulse, R is the battery internal resistance, and I_{char-max}, I_{dis-max}, Vₘᵢₙ, and Vₘₐₓ are preset or predetermined current and voltage limits.

The above equations calculate the next power command by assuming the battery resistance calculated from power pulse Pₖ is the same as for the next calculated power command value Pₖ₊₁. It is important to note that battery resistance may vary non-linearly with different magnitudes of power, especially at low temperatures, where battery resistance may vary by one-third or more between small and large power values. Nevertheless, this iterative updating strategy eventually approaches the actual voltage or current limited power capability value. This is because as the power is updated, the commanded power will become progressively closer to the SOP, and as the power approaches the SOP, the resistance calculated from the power pulse will be closer to the correct value. It may take more than 10 iterations to find the accurate power capability at extreme situations. To accelerate the SOP searching process, the present application proposes a novel way to estimate the resistance from previous power pulses. Instead of assuming the battery resistance is constant between two different power pulses, it is assumed to change linearly according to the voltage or current magnitude. First, the corresponding resistances from the last two power pulses for a given SOC breakpoint are calculated as Rₖ₋₁ and Rₖ. Then, the resistance's rate of change will be linearly estimated by the differential of resistance and voltage or current. Finally, the estimated resistance for the next-iteration power pulse \hat{R}ₖ₊₁ can be estimated by:

$$Current - limited case : \{ \begin{matrix}\frac{dR}{dI} = \frac{{R}_{k} - {R}_{k - 1}}{{I}_{k} - {I}_{k - 1}} \\ \hat{{R}_{k - 1}} = \frac{dR}{dI} \times ( {I}_{limit} - {I}_{k} ) + {R}_{k}\end{matrix} , and$$

$$Voltage - limited case : \{ \begin{matrix}\frac{dR}{dV} = \frac{{R}_{k} - {R}_{k - 1}}{{V}_{k} - {V}_{k - 1}} \\ \hat{{R}_{k - 1}} = \frac{dR}{dV} \times ( {V}_{limit} - {V}_{k} ) + {R}_{k}\end{matrix} .$$

The above-described iterative power command searching process to measure the SOP of the battery system 12 is graphically illustrated in the diagram of FIG. 2B. In a top row of plots (iteration 0), a CCCV test is applied as iteration 0 to obtain an initial power commands P_{CMD} as the battery system 12 is discharge, (e.g., in intervals of 10%). In a second row of plots (iteration 1), at least two of the stages (80% SOC and 10% SOC) have end voltage values that exceed the error tolerance (2.1V+/−0.05V) after applying the initial power commands as constant power pulses to the battery system. Thus, the power command P_{CMD} is updated and the process repeats. This continues until a fifth iteration (iteration 5, in the bottom row of plots), where the end voltage V_{end} is within the error tolerance at each SOC discharge stage. Thus, the iterative search process is complete and the final power command values are output as the SOP (the measured SOP of the battery system 12).

Referring now to FIGS. 3A-3E, example plots illustrating comparative performance of a conventional SOP estimation technique and the SOP measurement technique according to the principles of the present application are illustrated. In FIG. 3A, a comparison of the estimated SOP from an HPPC test and measured SOP from the SOP measurement technique of the present application are shown, with the measured SOP being less than the estimated SOP. In FIG. 3B, the voltage response after applying the measured SOP in comparison to using the estimated SOP is shown, and it can be seen that the more accurate measured SOP results in the voltage response just reaching (but not exceeding) the voltage limit whereas the estimate SOP (which is too large) exceeds the voltage limit. FIGS. 3C-3D similarly illustrate current and voltage responses after applying the estimated SOP from the HPPC test to the measured SOP using the iterative SOP measurement technique of the present application. Again, the current and voltage responses for the measured SOP just reaches voltage or current limits in all SOC breakpoint cases, whereas the current and voltage responses for the estimated SOP from the HPPC test deviate from the current/voltage limits and even reach more drastic critical safety limits. Finally, in FIG. 3E, the more accurate measured SOP provides for extended battery system usability (e.g., greater power available for application) at higher SOC levels compared to the estimated SOP from the HPPC test as well as avoidance of potential damage at lower SOC levels (too large of power casing voltage to fall below minimum).

It will be appreciated that the term “controller” as used herein refers to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. A state of power (SOP) measurement system for a battery system, the SOP measurement system comprising:
a set of sensors configured to measure a set of parameters of the battery system, the set of parameters including at least a state of charge (SOC) and a current or voltage of the battery system; and
a control system configured to determine an initial power command corresponding to a potential SOP of the battery system and perform an iterative power command searching process including:
preparing the battery system by charging the battery system to a fully-charged SOC;
discharging the battery system to a set of SOC breakpoints until the battery system reaches a fully-discharged SOC;
after reaching each SOC breakpoint, applying a power command as a constant power pulse to the battery system, the power command being the initial power command or a subsequently updated power command;
when a current or voltage of the battery system exceeds an error tolerance, updating the initial power command and repeating the iterative power command searching process; and
when the current or voltage of the battery system does not exceed the error tolerance, outputting the initial power command or the subsequently updated power command as a measured SOP of the battery system.

2. The SOP measurement system of claim 1, wherein the initial power command is a power based on an SOP estimation algorithm to be validated, and wherein the SOP estimation algorithm to be validated is one of a battery model-based SOP estimation algorithm and a machine learning-based SOP estimation algorithm.

3. The SOP measurement system of claim 1, wherein the initial power command is a power determined using a pulse-based battery test.

4. The SOP measurement system of claim 3, wherein the pulse-based battery test is one of a hybrid power pulse characterization (HPPC) test, a constant voltage (CV) test, a constant current (CC) test, and a constant current, constant voltage (CCCV) or constant power (CP) test.

5. The SOP measurement system of claim 1, wherein the fully-charged SOC is approximately 100% and the fully-discharged SOC is approximately 0%.

6. The SOP measurement system of claim 1, wherein:
the set of parameters of the battery system further includes an internal temperature of the battery system;
the battery system is placed in a thermal chamber that is temperature-controlled by the control system; and
the preparing of the battery system further includes the internal temperature of the battery system achieving a desired temperature.

7. The SOP measurement system of claim 1, wherein the iterative power capability searching technique further comprises determining an open circuit voltage (OCV) of the battery system after the discharging and a rest period.

8. The SOP measurement system of claim 1, wherein the discharging of the battery system is a constant discharge rate.

9. The SOP measurement system of claim 1, wherein the discharging of the battery system is a vehicle drive cycle discharge or a load profile for an application of interest.

10. The SOP measurement system of claim 9, wherein the battery system is a high voltage battery system of an electrified powertrain of an electrified vehicle, and wherein the control system is configured to output the measured SOP of the high voltage battery system into a controller of the electrified vehicle that utilizes the measured SOP of the high voltage battery system for control of the electrified powertrain.

11. A state of power (SOP) measurement method for a battery system, the SOP measurement method comprising:
providing a set of sensors configured to measure a set of parameters of the battery system, the set of parameters including at least a state of charge (SOC) and a current or voltage of the battery system; and
providing a control system configured to determine an initial power command corresponding to a potential SOP of the battery system and perform an iterative power command searching process including:
preparing the battery system by charging the battery system to a fully-charged SOC;
discharging the battery system to a set of SOC breakpoints until the battery system reaches a fully-discharged SOC;
after reaching each SOC breakpoint, applying a power command as a constant power pulse to the battery system, the power command being the initial power command or a subsequently updated power command;
when a current or voltage of the battery system exceeds an error tolerance, updating the initial power command and repeating the iterative power command searching process; and
when the current or voltage of the battery system does not exceed the error tolerance, outputting the initial power command or the subsequently updated power command as a measured SOP of the battery system.

12. The SOP measurement method of claim 11, wherein the initial power command is a power based on an SOP estimation algorithm to be validated, and wherein the SOP estimation algorithm to be validated is one of a battery model-based SOP estimation algorithm and a machine learning-based SOP estimation algorithm.

13. The SOP measurement method of claim 11, wherein the initial power command is a power using a pulse-based battery test.

14. The SOP measurement method of claim 13, wherein the pulse-based battery test is one of a hybrid power pulse characterization (HPPC) test, a constant voltage (CV) test, a constant current (CC) test, and a constant current, constant voltage (CCCV) or constant power (CP) test.

15. The SOP measurement method of claim 11, wherein the fully-charged SOC is approximately 100% and the fully-discharged SOC is approximately 0%.

16. The SOP measurement method of claim 11, wherein:
the set of parameters of the battery system further includes an internal temperature of the battery system;
the battery system is placed in a thermal chamber that is temperature-controlled by the control system; and
the preparing of the battery system further includes the internal temperature of the battery system achieving a desired temperature.

17. The SOP measurement method of claim 11, wherein the iterative power capability searching technique further comprises determining an open circuit voltage (OCV) of the battery system after the discharging and a rest period.

18. The SOP measurement method of claim 11, wherein the discharging of the battery system is a constant discharge rate.

19. The SOP measurement method of claim 11, wherein the discharging of the battery system is a vehicle drive cycle discharge or a load profile for an application of interest.

20. The SOP measurement method of claim 19, wherein the battery system is a high voltage battery system of an electrified powertrain of an electrified vehicle, and wherein the control system is configured to output the measured SOP of the high voltage battery system into a controller of the electrified vehicle that utilizes the measured SOP of the high voltage battery system for control of the electrified powertrain.
